(19) United States
(12) Patent Application Publication
(10) Pub. No.: US 2014/0151769 A1
(43) Pub. Date: Jun. 5, 2014

(54) DETECTION APPARATUS AND RADIATION DETECTION SYSTEM

(71) Applicant: CANON KABUSHIKI KAISHA, TOKYO (JP)

(72) Inventors: Hiroshi Wayama, Saitama-shi (JP); Minoru Watanabe, Honjo-shi (JP); Keigo Yokoyama, Honjo-shi (JP); Masato Ofuji, Honjo-shi (JP); Jun Kawanabe, Kumagaya-shi (JP); Kentaro Fujiyoshi, Tokyo (JP); Akiya Nakayama, Kawasaki-shi (JP)

(73) Assignee: CANON KABUSHIKI KAISHA, TOKYO (JP)

(21) Appl. No.: 14/084,716

(22) Filed: Nov. 20, 2013

(30) Foreign Application Priority Data
Dec. 3, 2012 (JP) 2012-264742

(51) Int. Cl. H01L 27/146

(52) U.S. Cl. CPC H01L 27/14603
USPC 257/291

(57) ABSTRACT

A detection apparatus includes a conversion layer configured to convert incident light or radiation into a charge, electrodes configured to collect a charge produced as a result of the conversion by the conversion layer, and impurity semiconductor layers arranged between the electrodes and the conversion layer. The conversion layer is arranged over the electrodes so as to cover the electrodes. A part of the conversion layer which covers a region between an adjacent pair of the electrodes includes a portion smaller in film thickness than a part of the conversion layer which covers edges of the electrodes.

### BACKGROUND OF THE INVENTION

1. Field of the Invention

The present disclosure relates to a detection apparatus and a radiation detection system.

2. Description of the Related Art

In recent years, manufacturing technology for a liquid crystal panel using thin-film transistors (TFTs) has been used for a detection apparatus. In such a detection apparatus, aperture ratio improvements are achieved by forming conversion elements at locations where TFTs are covered. The conversion element has a PIN structure in which, for example, a p-type semiconductor layer, intrinsic semiconductor layer, and n-type semiconductor layer are accumulated and the intrinsic semiconductor layer functions as a photoelectric conversion layer. To improve quantity of charge and SNR, U.S. Pat. No. 5,619,033 proposes a detection apparatus which realizes an aperture ratio of 100% by forming a photoelectric conversion layer over an entire pixel array and placing electrodes adapted to collect the charge generated by the photoelectric conversion layer, on a pixel by pixel basis.

### SUMMARY OF THE INVENTION

In the detection apparatus according to U.S. Pat. No. 5,619,033, a top face of the photoelectric conversion layer is configured to be flat. With this configuration, the quantity of charge and SNR cannot be improved sufficiently as described later. Thus, an aspect of the present invention provides a technique advantageous for a detection apparatus in which a conversion layer is formed over a pixel array.

According to some embodiments, a detection apparatus comprising a conversion layer configured to convert incident light or radiation into a charge, a plurality of first electrodes configured to collect a charge produced as a result of the conversion by the conversion layer, and a plurality of first impurity semiconductor layers arranged between the plurality of first electrodes and the conversion layer is provided. The conversion layer is arranged over the plurality of first electrodes so as to cover the plurality of first electrodes. A part of the conversion layer which covers a region between an adjacent pair of the first electrodes includes a portion smaller in film thickness than a part of the conversion layer which covers edges of the first electrodes.

Further features of the present invention will become apparent from the following description of exemplary embodiments (with reference to the attached drawings).

### BRIEF DESCRIPTION OF THE DRAWINGS

FIG. 1 is a diagram describing an example of overall configuration of a detection apparatus according to an embodiment of the present invention.

FIGS. 2A to 2C are diagrams describing a detailed configuration example of the detection apparatus according to the embodiment of the present invention.

FIG. 3 is a diagram describing potential distributions of the detection apparatus according to the embodiment of the present invention.

FIGS. 4A to 4I are diagrams describing an example of a manufacturing method for the detection apparatus according to the embodiment of the present invention.

FIG. 5 is a diagram describing a natural oxide film produced in the detection apparatus according to the embodiment of the present invention.

FIGS. 6A to 6C are diagrams describing another example of the manufacturing method for the detection apparatus according to the embodiment of the present invention.

FIG. 7 is a diagram describing a configuration of a radiation detection apparatus according to the embodiment of the present invention.

### DESCRIPTION OF THE EMBODIMENTS

Embodiments of the present invention will be described below in detail with reference to the accompanying drawings. Throughout various embodiments, similar components are denoted by the same reference numerals, and redundant description thereof will be omitted. Also, each embodiment can be changed as appropriate, and different embodiments can be used in combination. Generally the present invention is applicable to a detection apparatus in which a conversion layer is formed over a pixel array containing plural pixels. Conversion elements of a PIN structure will be described below by way of example, but conversion elements of a NIP structure with an opposite conductivity type or conversion elements of a MIS structure may be used alternatively. Similarly, bottom-gate thin-film transistors will be described below by way of example, but top-gate thin-film transistors may be used alternatively. The transistors may be made of either amorphous silicon or polysilicon. Also, electromagnetic waves herein range from those in the wavelength region of light to those in the wavelength region of radiation and include visible to infrared light rays as well as radiation such as x-rays, alpha rays, beta rays, and gamma rays.

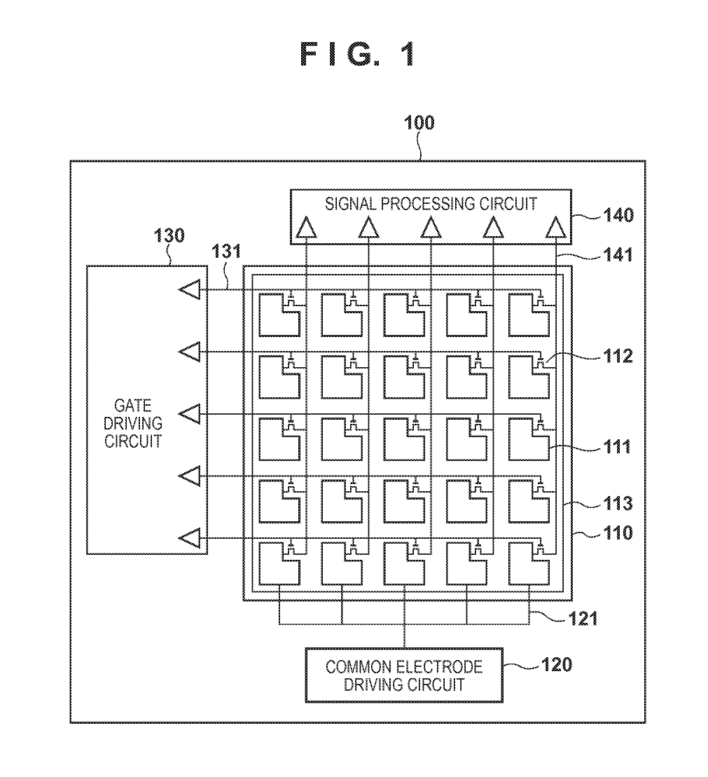

An overall configuration of a detection apparatus 100 according to some embodiments of the present invention will be described with reference to FIG. 1. The detection apparatus 100 includes a pixel array 110, a common electrode driving circuit 120, a gate driving circuit 130, and a signal processing circuit 140. The pixel array 110 has plural pixels arranged in an array. The pixel array 110 has, for example, about 3000 rows by 3000 columns of pixels, but is shown as having 5 rows by 5 columns of pixels in FIG. 1 for purposes of explanation.

Each pixel includes a conversion element 111 and a transistor 112. The conversion element 111 generates a charge corresponding to electromagnetic waves received by the detection apparatus 100. The conversion element 111 may be a photoelectric conversion element adapted to convert visible light, converted from radiation by a scintillator, into a charge or may be a conversion element adapted to convert radiation directed at the detection apparatus 100 directly into a charge. The transistor 112 is, for example, a thin-film transistor. The conversion element 111 and a first main electrode (source or drain) of the transistor 112 are electrically connected to each other. Although the conversion element 111 and transistor 112 are illustrated in FIG. 1 as being adjacent to each other in a direction parallel to a substrate surface, the conversion element 111 and transistor 112 are placed by overlapping each other in a direction perpendicular to the substrate surface as described later. The pixel array 110 further includes a common electrode 113 placed commonly to plural pixels.

The common electrode driving circuit 120 is connected to the common electrode 113 via a driving line 121 and adapted to control a drive voltage supplied to the common electrode 113. The gate driving circuit 130 is connected to a gate of the transistor 112 through a gate line 131 and adapted to control conduction of the transistor 112. The signal processing circuit 140 is connected to a second main electrode (drain or source) of the transistor 112 via a signal line 141 and adapted to read a signal out of the conversion element 111.

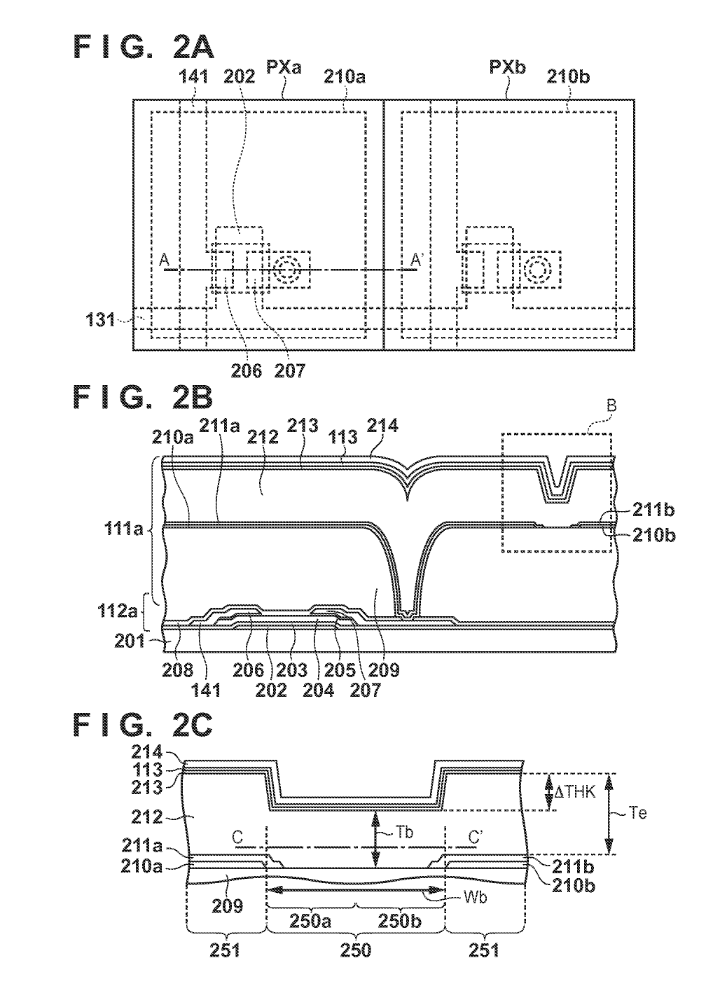

Next, a detailed configuration of the pixels of the detection apparatus 100 will be described with reference to FIGS. 2A to 2C. FIG. 2A is a plan view focusing on two adjacent pixels PXa and PXb contained in the pixel array 110, FIG. 2B is a sectional view taken along line A-A′ in FIG. 2A, and FIG. 2C is an enlarged view of region B in FIG. 2B. Every pixel of the pixel array 110 may have a same configuration, and thus a configuration of the pixel PXa will mainly be described below.

The pixel array 110 is placed on a substrate 201, and each pixel in the pixel array 110 has a conversion element 111 and transistor 112. The pixel PXa includes a conversion element 111a as the conversion element 111, and a transistor 112a as the transistor 112. The transistor 112a includes a gate electrode 202, an insulating layer 203, an intrinsic semiconductor layer 204, an impurity semiconductor layer 205, a first main electrode 206, and a second main electrode 207. The gate electrode 202 is provided separately for each pixel. The insulating layer 203 is formed over the pixel array 110, covering the gate electrodes 202 of each of the pixels. That part of the insulating layer 203 which covers the gate electrode 202 functions as a gate insulating film of the transistor 112a. The intrinsic semiconductor layer 204 is provided separately for each pixel at such a location as to cover the gate electrode 202 via the insulating layer 203. A channel of the transistor 112a is formed in the intrinsic semiconductor layer 204. One end of the first main electrode 206 is placed on the intrinsic semiconductor layer 204 via the impurity semiconductor layer 205, and the other end is connected to the signal line 141. One end of the second main electrode 207 is placed on the intrinsic semiconductor layer 204 via the impurity semiconductor layer 205, and the other end extends outside the intrinsic semiconductor layer 204. The impurity semiconductor layer 205 reduces contact resistance between the intrinsic semiconductor layer 204 and the first and second main electrodes 206 and 207.

The detection apparatus 100 further includes a protective layer 208 formed over the pixel array 110, covering the transistors 112. The protective layer 208 has an opening to expose part of the second main electrode 207. A planarizing layer 209 is formed on the protective layer 208, spreading over the pixel array 110. The planarizing layer 209 has an opening adapted to expose the opening in the protective layer 208 and consequently expose part of the second main electrode 207. The planarizing layer 209 enables stable formation of the conversion element 111a and allows reduction of parasitic capacitance between the transistor 112a and conversion element 111a.

The detection apparatus 100 includes a discrete electrode 210a, an n-type semiconductor layer 211a, an intrinsic semiconductor layer 212, a p-type semiconductor layer 213, and a common electrode (the second electrode) 113 in order of increasing distance from the substrate 201, making up the conversion element 111a. That is, the conversion element 111a has a PIN structure. Both discrete electrode 210a (first electrode) and n-type semiconductor layer (first impurity semiconductor layer) 211a are provided separately for each pixel. The intrinsic semiconductor layer 212, p-type semiconductor layer 213 (second impurity semiconductor layer), and common electrode (second electrode) 113 are formed over the pixel array 110. The discrete electrode 210a is put in contact with the second main electrode 207 of the transistor 112a through the opening in protective layer 208 and opening in the planarizing layer 209, thereby electrically connecting the discrete electrode 210a and transistor 112a to each other. The intrinsic semiconductor layer 212 functions as a conversion layer and generates a charge corresponding to received electromagnetic waves. The charge generated by that part of the intrinsic semiconductor layer 212 which covers the discrete electrode 210a is collected by the discrete electrode 210a. The detection apparatus 100 further includes a protective layer 214 formed over the pixel array 110, covering the conversion elements 111.

A configuration around a region between the pixels PXa and PXb will be described with reference to FIG. 2C. The conversion element 111 of the pixel PXb has a discrete electrode 210b and an n-type semiconductor layer 211b. Film thickness Tb of that portion (referred to as a boundary covering portion 250) of the intrinsic semiconductor layer 212 which covers a region between the discrete electrodes 210a and 210b is smaller than film thickness Te of that portion (referred to as an edge covering portion 251) of the intrinsic semiconductor layer 212 which covers edges of the discrete electrodes 210a and 210b. Advantages of this configuration will be described below.

That half portion of the boundary covering portion 250 which is closer to the discrete electrode 210a is referred to as a left portion 250a while a half portion closer to the discrete electrode 210b is referred to as a right portion 250b. Desirably, the charge produced in the left portion 250a is collected by the discrete electrode 210a while the charge produced in the right portion 250b is collected by the discrete electrode 210b. Hereinafter the charges collected in this way are described as having been collected properly. However, when an electric field in the boundary covering portion 250 is weak, the question as to which of the discrete electrodes 210a and 210b the charge produced in the boundary covering portion 250 is collected by depends on probability. Noise will result when the charge produced in the right portion 250b is collected by the discrete electrode 210a or the charge produced in the left portion 250a is collected by the discrete electrode 210b. Also, when the electric field in the boundary covering portion 250 is weak, the charge produced in the boundary covering portion 250 may vanish without being collected by either of the discrete electrodes 210a and 210b. This will cause reduction in quantity of signals detected by the detection apparatus 100. Furthermore, when the electric field in the boundary covering portion 250 is weak, requiring time for the charges to reach the discrete electrodes 210a and 210b, a residual image will appear, also causing noise. In either case, when the electric field in the boundary covering portion 250 is weak, the SNR (signal-to-noise ratio) can deteriorate. With the detection apparatus 100 according to the present embodiment, the electric field in the boundary covering portion 250 can be made stronger by making the film thickness Tb of the boundary covering portion 250 smaller than the film thickness Te of the edge covering portion 251.

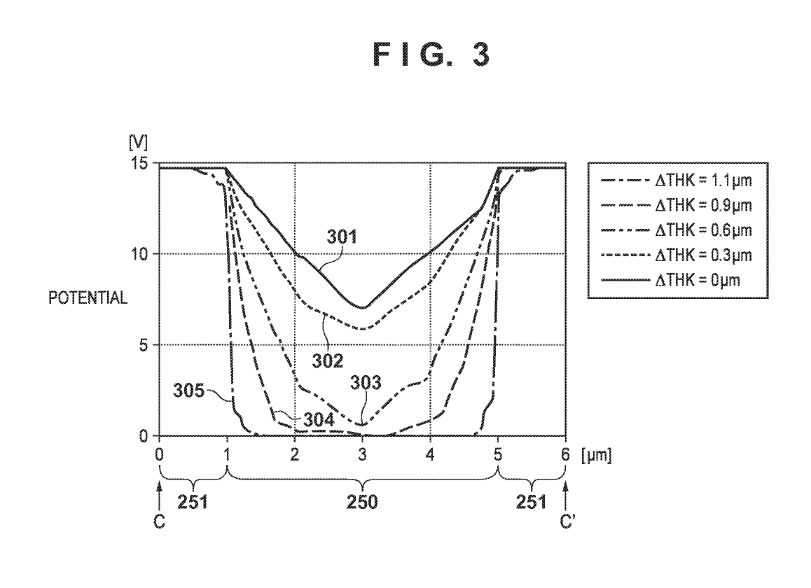

Changes in potential distributions taking place along line C-C′ in FIG. 2C when the film thickness Tb of the boundary covering portion 250 is changed will be described with reference to FIG. 3. Line C-C′ is taken at a location right above the n-type semiconductor layers 211a and 211b. If ΔTHK is a difference between a top face of the boundary covering portion 250 and a top face of the edge covering portion 251, FIG. 3 graphically shows potential distributions taking place along line C-C′ for different values of ΔTHK. Specifically, graph lines 301 to 305 represent potential distributions produced when the values of ΔTHK are 0 μm, 0.3 μm, 0.6 μm, 0.9 μm, and 1.1 μm, respectively. When ΔTHK is 0 μm, an upper end of the intrinsic semiconductor layer 212 is substantially flat, which is equal to the configuration proposed in U.S. Pat. No. 5,619,033. The larger the value of ΔTHK, the smaller the film thickness Tb of the boundary covering portion 250. For each graph line, the abscissa represents a position on line C-C′ while the ordinate represents the potential. On the abscissa, the original point is set at the position of C and the right direction (direction toward C′) corresponds to a positive direction. The potential distributions were created from simulation values obtained by applying a voltage of 15 V to the discrete electrodes 210a and 210b, and a voltage of 0 V to the common electrode 113, with a width Wb of the boundary covering portion 250 set to 4 μm and with the film thickness Te of the edge covering portion 251 set to 1.2 μm.

Generally the electric field is given by a space derivative of the potential distribution, and a force exerted on the charge is proportional to electric field strength. As shown in FIG. 3, outside the boundary covering portion 250 (on the side closer to the edge covering portion 251), the larger the value of ΔTHK, the smaller the value of the potential of the boundary covering portion 250, and thus steeper the slope of the potential distribution. Thus, the larger the value of ΔTHK and the smaller the film thickness Tb of the boundary covering portion 250, the stronger the force acting on the charge in such a direction that the charge will be collected properly, which improves the SNR.

On the other hand, inside the boundary covering portion 250 (in a central portion of the boundary covering portion 250), the larger the value of ΔTHK, the smaller the value of the potential of the boundary covering portion 250, but the value of the potential stops decreasing when the potential equals to 0 V (voltage of the discrete electrodes 210a and 210b). If the value of ΔTHK is further increased in this state, a range in which the potential is approximately 0 V increases. For example, when ΔTHK represented by graph line 303 is 0.6 μm, the potential becomes approximately 0 V in the center of the boundary covering portion 250. When ΔTHK represented by graph line 304 is 0.9 μm, the potential becomes approximately 0 V in approximately half the area of the boundary covering portion 250. When ΔTHK represented by graph line 305 is 1.1 μm, the potential becomes approximately 0 V in most area of the boundary covering portion 250. In the area in which the potential remains constant at approximately 0 V, since no force acts on the charge, the SNR decreases for the reasons described above. Also, if the film thickness Tb of the boundary covering portion 250 is too small, this will cause increases in dark current.

In this way, decreases in the film thickness Tb of the boundary covering portion 250 improve SNR, but the SNR falls when the film thickness Tb decreases further than a predetermined value. For example, in the example of FIG. 3, ΔTHK may be set to 0.6 μm to obtain the potential distribution represented by graph line 303. In this case, the potential becomes equal to approximately 0 V at one point of the potential distribution, and nowhere does the potential gradient become 0. Generally, a minimum value of the film thickness Tb of the boundary covering portion 250 can be designed to be one-third or more of the film thickness Te of the edge covering portion 251.

In the simulation shown in FIG. 3, the width Wb of the boundary covering portion 250 was set to 4 μm. However, the width Wb may be set to another value, for example, to around 1 μm or 500 nm, or around 20 μm or below. According to the present embodiment, by reducing the film thickness Tb of the boundary covering portion 250, it is possible to change the potential distribution in the corresponding part and thereby improve the quantity of detected signal and SNR.

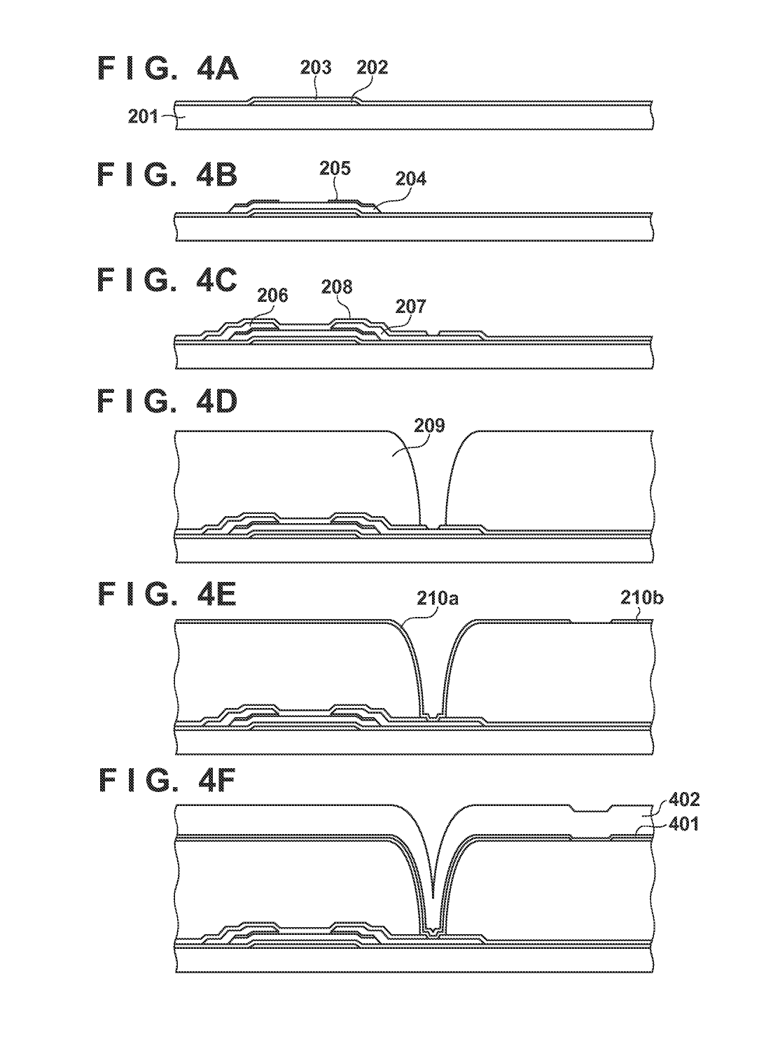

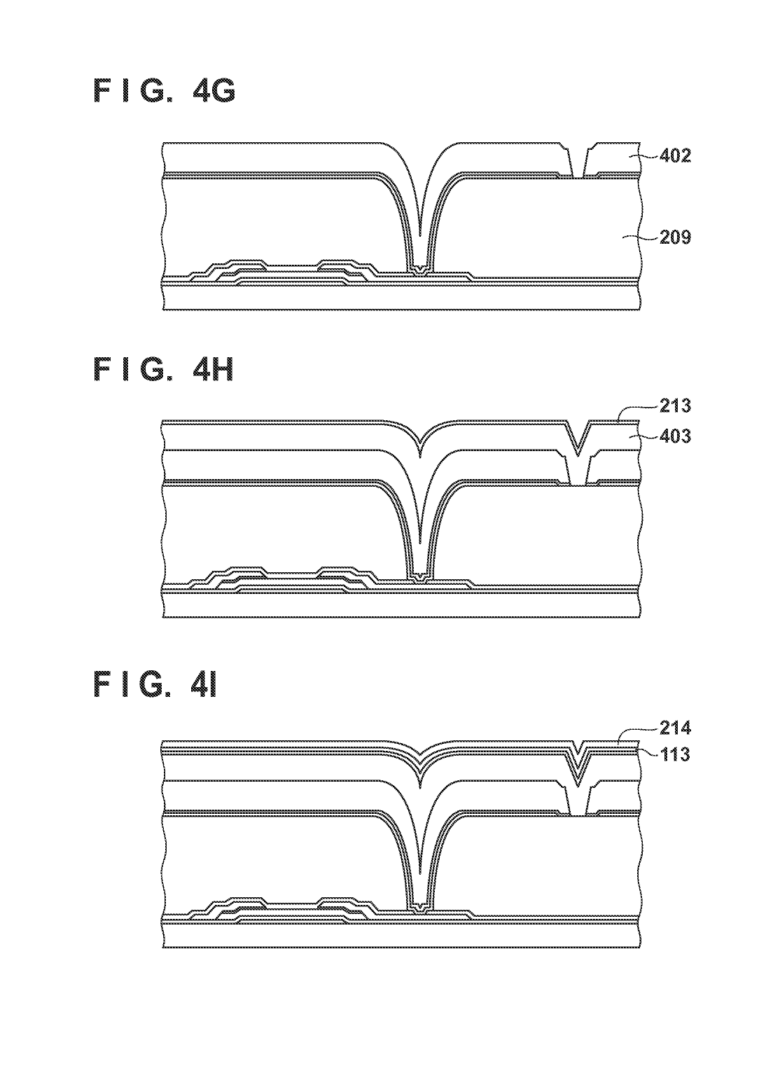

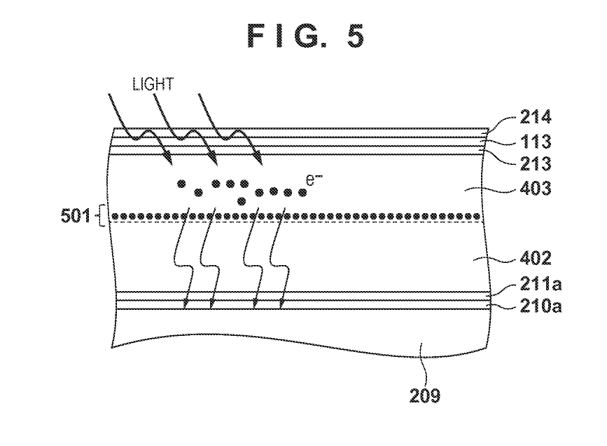

Next, an example of a manufacturing method for the detection apparatus 100 will be described with reference to FIGS. 4A to 4I. FIGS. 4A to 4I are sectional views corresponding to the sectional view of FIG. 2B and to individual manufacturing processes. First, as shown in FIG. 4A, the gate electrode 202 of the transistor 112 is formed on the substrate 201, and the insulating layer 203 is deposited thereon. The gate electrode 202 is formed, for example, by patterning a metal layer deposited on the entire surface of the substrate 201 by a sputtering machine. The metal layer is, for example, 150 nm to 700 nm thick and is made of a low-resistance metal such as Al, Cu, Mo, or W; or an alloy or laminate thereof. The insulating layer 203 is made, for example, of silicon nitride film (SiN). The film thickness of the insulating layer 203 is set, for example, to 150 nm to 600 nm to increase capacity of the gate insulating film while maintaining a breakdown voltage of the transistor 112, for example, at around 200 V.

Next, as shown in FIG. 4B, the intrinsic semiconductor layer 204 is formed on the insulating layer 203, and the impurity semiconductor layer 205 is formed thereon. The intrinsic semiconductor layer 204 is formed by etching a deposited intrinsic semiconductor layer in an island pattern. The intrinsic semiconductor layer 204 is set to be, for example, 100 nm to 250 nm thick so as to reduce series resistance of the transistors 112 and so as to be thick enough not to be removed by etching when the impurity semiconductor layer 205 is formed. The impurity semiconductor layer 205 is formed by etching a deposited impurity semiconductor layer in an island pattern and then removing a central portion (portion covering a channel area) thereof. The impurity semiconductor layer 205 may have any thickness as long as junction between the intrinsic semiconductor layer 204 and the first and second main electrodes 206 and 207 is allowed for, and may be, for example, 20 nm to 70 nm thick.

Next, as shown in FIG. 4C, the signal line 141, first main electrode 206, and second main electrode 207 are formed, and then the protective layer 208 is formed thereon. The signal line 141, first main electrode 206, and second main electrode 207 are formed, for example, by patterning a metal layer deposited on the entire surface of the substrate 201 by a sputtering machine. The metal layer is, for example, 150 nm to 800 nm thick and is made of a low-resistance metal such as Al, Cu, Mo, or W; or an alloy or laminate thereof. The protective layer 208 is formed by depositing an insulating layer on the entire surface of the substrate 201 and then removing part of the insulating layer so as to expose part of the second main electrode 207. The film thickness of the protective layer 208 is, for example, 200 nm to 500 nm.

Next, the planarizing layer 209 is formed as shown in FIG. 4D. The planarizing layer 209 is formed by depositing an organic layer on the entire surface of the substrate 201 and then removing part of the organic layer so as to expose the opening in the protective layer 208. The planarizing layer 209 is configured to be, for example, 1 μm to 5 μm in film thickness so as to achieve the function of the planarizing layer 209 described above.

Next, the discrete electrodes 210a and 210b are formed as shown in FIG. 4E. The discrete electrodes 210a and 210b are formed, for example, by patterning a metal layer deposited on the entire surface of the substrate 201. The discrete electrodes 210a and 210b may be transparent electrodes made of ITO or the like, and can be configured to be about a few tens of nm in thickness in that case. Alternatively, the discrete electrodes 210a and 210b may be made of a low-resistance metal such as Al, Cu, Mo, or W; or an alloy or laminate thereof, and can be configured to be, for example, about 50 nm to 300 nm thick in that case.

Next, as shown in FIG. 4F, an n-type semiconductor layer 401 is formed on the entire surface of the substrate 201, and then an intrinsic semiconductor layer 402 is formed thereon, covering the entire surface of the substrate 201. The n-type semiconductor layer 401 and intrinsic semiconductor layer 402 are deposited continuously by the same deposition apparatus (e.g., CVD apparatus). First, the substrate 201 subjected to the process of FIG. 4E is set up in the deposition apparatus, and the n-type semiconductor layer 401 is deposited to a thickness of, for example, 10 nm to 100 nm. Subsequently, the gas is changed, with the substrate 201 kept in the deposition apparatus, and the intrinsic semiconductor layer 402 is deposited to a thickness of, for example, 30 nm to 100 nm.

Next, as shown in FIG. 4G, the n-type semiconductor layer 401 and intrinsic semiconductor layer 402 are patterned, and a portion covering portions free of the discrete electrodes 210a and 210b is removed. Consequently, the n-type semiconductor layer 401 is divided into pixel-by-pixel, n-type semiconductor layers 211a and 211b.

Next, as shown in FIG. 4H, an intrinsic semiconductor layer 403 is formed on the entire surface of the substrate 201, and then the p-type semiconductor layer 213 is formed thereon, covering the entire surface of the substrate 201. The intrinsic semiconductor layer 403 and p-type semiconductor layer 213 are deposited continuously by the same deposition apparatus (e.g., CVD apparatus). First, the substrate 201 subjected to the process of FIG. 4G is set up in the deposition apparatus, and the intrinsic semiconductor layer 403 is deposited to a thickness of, for example, 300 nm to 2000 nm. Subsequently, the gas is changed, with the substrate 201 kept in the deposition apparatus, and the p-type semiconductor layer 213 is deposited to a thickness of, for example, about a few tens of nm. The two intrinsic semiconductor layers 402 and 403 described above make up the intrinsic semiconductor layer 212 of FIGS. 2A to 2C.

Next, as shown in FIG. 4I, the common electrode 113 is formed, and then the protective layer 214 is formed thereon, covering the entire surface of the substrate 201. The common electrode 113 is formed, for example, by depositing a metal layer on the entire surface of the substrate 201. The common electrode 113 may be a transparent electrode made of ITO or the like, and can be configured to be about a few tens of nm thick in that case. Alternatively, the common electrode 113 may be made of a low-resistance metal such as Al, Cu, Mo, or W; or an alloy or laminate thereof, and can be configured to be, for example, about 300 nm to 700 nm thick in that case. The protective layer 214 is formed, for example, by depositing an insulating layer on the entire surface of the substrate 201. Subsequently, the detection apparatus 100 having a sectional structure shown in FIG. 2B is produced, for example, by forming remaining components by a known method.

If the intrinsic semiconductor layer 212 is deposited by being divided into the intrinsic semiconductor layer 402 and intrinsic semiconductor layer 403 and the n-type semiconductor layer 401 and intrinsic semiconductor layer 402 are deposited continuously by the same deposition apparatus, as in the case of the method described above, it is possible to curb generation of a natural oxide film on the surface of the n-type semiconductor layer 401. Also, if the n-type semiconductor layer 401 is patterned after being deposited, the n-type semiconductor layer 401 may peel off because of the small film thickness. However, when patterning is done after the n-type semiconductor layer 401 and intrinsic semiconductor layer 402 are deposited as with the above method, since the total film thickness of these layers is at least 30 nm, peeling is less likely to occur.

When the n-type semiconductor layer 401 and intrinsic semiconductor layer 402 are patterned, a natural oxide film 501 is produced on the surface of the intrinsic semiconductor layer 402. However, since an oxidation rate of the intrinsic semiconductor layer is generally smaller than an oxidation rate of the n-type semiconductor layer, the film thickness of the natural oxide film can be reduced compared to when a natural oxide film is produced on the surface of the n-type semiconductor layer 401, and consequently junction resistance can be reduced. Furthermore, in the above method, because the natural oxide film 501 is located away from the discrete electrode 210a, when, for example, the charge accumulated by photoelectric conversion is transferred to the transistor 112a, the influence on a neighborhood of the electrode on which the charge is accumulated is reduced. To keep the natural oxide film 501 away from both the discrete electrode 210a and common electrode 113, the n-type semiconductor layer 401 and intrinsic semiconductor layer 402 may be configured to be about equal to each other in thickness. For example, each of the layers may be set to a film thickness of 300 nm to 1000 nm.

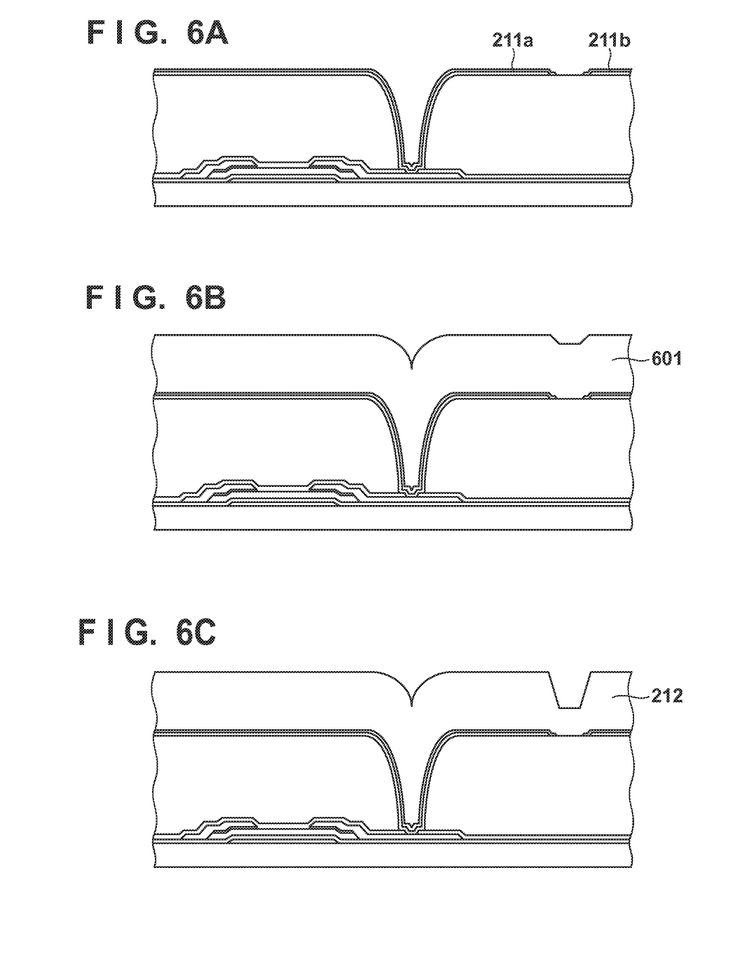

Next, another example of the manufacturing method for the detection apparatus 100 in FIG. 1 will be described with reference to FIGS. 6A to 6C. With this manufacturing method, the intrinsic semiconductor layer 212 is deposited by one film deposition process. First, components up to the discrete electrodes 210a and 210b are formed by carrying out processes up to the process of FIG. 4E described above. As shown in FIG. 6A, the n-type semiconductor layer is deposited and the portion covering the region between the discrete electrodes 210a and 210b is removed to form the n-type semiconductor layers 211a and 211b. Next, as shown in FIG. 6B, the intrinsic semiconductor layer 601 is deposited. Next, as shown in FIG. 6C, the intrinsic semiconductor layer 212 is formed by etching the intrinsic semiconductor layer 601 so as to reduce the thickness of the portion covering the region between the discrete electrodes 210a and 210b. The etching is performed for a period of time sufficient to leave an appropriate film thickness. Subsequently, the detection apparatus 100 is completed in a manner similar to FIG. 4H and subsequent processes.

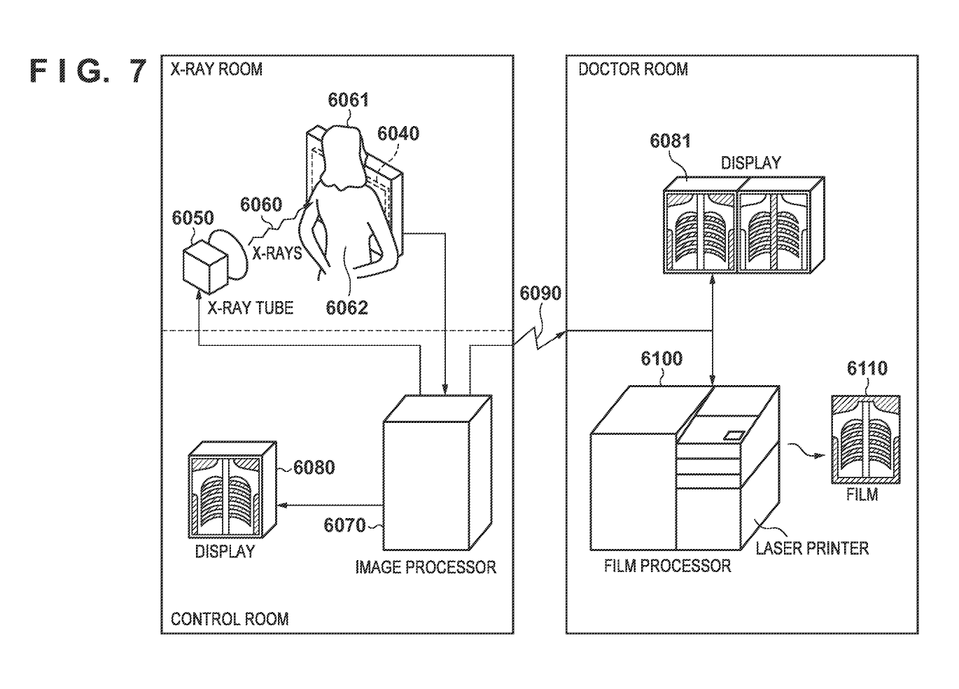

FIG. 7 is a diagram showing an example in which the radiation detection apparatus according to the present invention is applied to an x-ray diagnostic system (radiation detection system). Radiation, i.e., x-rays 6060, generated by an x-ray tube 6050 (radiation source) penetrates the chest 6062 of a subject or patient 6061 and enter a detection apparatus 6040, which is the detection apparatus according to the present invention with a scintillator provided in upper part. Here, the detection/conversion apparatus with a scintillator provided in the upper part makes up a radiation detection apparatus. The incident x-rays contains internal bodily information about the patient 6061. The scintillator emits light in response to the incident x-rays, and electrical information is obtained through photoelectric conversion of the emitted light. The electrical information is converted into a digital signal and then subjected to image processing by an image processor 6070, serving as a signal processing unit, to allow observation on a display 6080 serving as a display unit of a control room. Note that the radiation detection system includes at least the detection apparatus and a signal processing unit adapted to process a signal from the detection apparatus.

Also, this information can be transferred to a remote location by a transmission processing unit such as a telephone circuit 6090, displayed on a display 6081 serving as a display unit or saved on a recording unit such as an optical disk in a doctor room or the like at another location, allowing doctors at the remote location to carry out a diagnosis. Also, the information can be recorded by a film processor 6100 serving as a recording unit on a film 6110 serving as a recording medium.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-264742, filed Dec. 3, 2012 which is hereby incorporated by reference herein in its entirety.

What is claimed is:

1. A detection apparatus comprising:
a conversion layer configured to convert incident light or radiation into a charge;
a plurality of first electrodes configured to collect a charge produced as a result of the conversion by said conversion layer; and
a plurality of first impurity semiconductor layers arranged between said plurality of first electrodes and said conversion layer,
wherein said conversion layer is arranged over said plurality of first electrodes so as to cover said plurality of first electrodes, and
a part of said conversion layer which covers a region between an adjacent pair of said first electrodes includes a portion smaller in film thickness than a part of said conversion layer which covers edges of said first electrodes.

2. The detection apparatus according to claim 1, further comprising a plurality of transistors electrically connected to said plurality of first electrodes, wherein
each of said plurality of transistors are respectively arranged in positions covered by an electrode of said plurality of first electrodes electrically connected with the transistor.

3. The detection apparatus according to claim 1, wherein said conversion layer is recessed in the part which covers the region between the adjacent pair of said first electrodes.

4. The detection apparatus according to claim 1, further comprising a second impurity semiconductor layer and a second electrode arranged in this order above said conversion layer, spreading over said plurality of first electrodes, wherein:
said conversion layer includes an intrinsic semiconductor layer; and
said plurality of first impurity semiconductor layers and said second impurity semiconductor layer differ from each other in conductivity type.

5. The detection apparatus according to claim 4, wherein said second impurity semiconductor layer and said second electrode are recessed in the part which covers the region between the adjacent pair of said first electrodes.

6. The detection apparatus according to claim 1, wherein a minimum value of a film thickness of the part of said conversion layer which covers the region between the adjacent pair of said first electrodes is one-third or more of a film thickness of the part of said conversion layer which covers the edges of said first electrodes.

7. A radiation detection system comprising:
the detection apparatus according to claim 1; and
a signal processing unit adapted to process a signal obtained by said detection apparatus.
